(19) United States
(12) Patent Application Publication
(10) Pub. No.: US 2017/0164488 A1
(43) Pub. Date: Jun. 8, 2017

(54) ELECTRICAL JUNCTION BOX

(71) Applicants: AUTONETWORKS TECHNOLOGIES, LTD., Yokkaichi, Mie (JP); SUMITOMO WIRING SYSTEMS, LIMITED, Yokkaichi, Mie (JP); SUMITOMO ELECTRIC INDUSTRIES, LIMITED, Osaka-shi, Osaka (JP)

(72) Inventors: Yoshikazu SASAKI, Yokkaichi (JP); Junya AICHI, Yokkaichi (JP); Kyungwoo KIM, Yokkaichi (JP); Shigeki YAMANE, Yokkaichi (JP); Takehito KOBAYASHI, Yokkaichi (JP); Yukinori KITA, Yokkaichi (JP); Tomohiro OOI, Yokkaichi (JP)

(73) Assignees: AUTONETWORKS TECHNOLOGIES, LTD., Yokkaichi Mie (JP); SUMITOMO WIRING SYSTEMS, LIMITED, Yokkaichi Mie (JP); SUMITOMO ELECTRIC INDUSTRIES, LIMITED, Osaka-shi, Osaka (JP)

(21) Appl. No.: 15/321,565

(22) PCT Filed: Jun. 30, 2015
(86) PCT No.: PCT/JP2015/068768

§ 371 Date: Dec. 22, 2016

(30) Foreign Application Priority Data
Jul. 2, 2014 (JP) 2014-136486

(51) Int. Cl. H05K 5/00; H02G 3/08; H05K 1/14

(52) U.S. Cl. CPC H05K 5/0026; H05K 1/14; H02G 3/08

(57) ABSTRACT

An electrical junction box includes a first circuit board that includes electroconductive paths; a second circuit board that includes electroconductive paths; a terminal module including (i) a plurality of terminals that connect the electroconductive paths of the first circuit board and the electroconductive paths of the second circuit board and (ii) an insulative connecting member that connects the plurality of terminals; and a retaining member that retains at least one of the first and second circuit boards. The retaining member has a fitting portion into which the connecting member is fitted.

### TECHNICAL FIELD

This invention relates to an electrical junction box.

### BACKGROUND TECHNOLOGY

Conventionally, a technology is known in which a plurality of terminals connected by resin are soldered to electroconductive paths of circuit boards. In Patent Reference 1, first and second circuit boards are arranged facing each other, a plurality of relay terminal portions are connected to each other, and one end of the plurality of relay terminal portions is soldered to the first circuit board, and the other end side of the plurality of relay terminal portions is soldered to the second circuit board.

### PRIOR ART REFERENCE

### Patent Reference

Patent Reference 1: P2013-70567A

### SUMMARY OF THE INVENTION

### Problem to be Resolved by the Invention

Incidentally, in the structure of Patent Reference 1, the plurality of relay terminal portions needs to be inserted into through holes of the first and second circuit boards in order to solder the plurality of relay terminal portions to the first and second circuit boards. Here, when inserting the plurality of relay terminal portions through the through holes, an assembly operation normally needs to be performed, which uses a jig for aligning the plurality of relay terminal. portions and the through holes. Thus, there is a problem that the assembly operation becomes troublesome.

This invention was completed based on the above situation. An object of this invention is to simplify an operation of assembling a plurality of terminals to circuit boards.

### Means of Solving the Problem

An electrical junction box is provided with (i) a first circuit board having electroconductive paths, (ii) a second circuit board having electroconductive paths, (iii) a terminal module including (a) a plurality of terminals that connect the electroconductive paths of the first circuit board and the electroconductive paths of the second circuit board and (b) an insulative connecting member that connects the plurality of terminals, and (iv) a retaining member that retains at least one of the first and second circuit boards, wherein the retaining member has a fitting portion into which the connecting member is fitted.

According to this structure, if the connecting member is fit into the fitting portion of the retaining member, positions of the plurality of terminals with respect to the retaining member can be fixed via the connecting member. Thus, even if a jig is not used, the plurality of terminals can be connected to the electroconductive paths of the first and second circuit boards. Thus, the operation of assembling the plurality of terminals to the circuit boards can be simplified.

The following embodiment is preferred as an embodiment of this invention.
The fitting portion is provided with (i) a pair of side walls that is arranged so as to sandwich the connecting member and (ii) a connecting wall that is arranged along a direction in which the multiple terminals are aligned and connects the pair of side walls.

If the terminal module is long in a direction in which the terminals are aligned, inclination of the terminal module can be easily generated in a direction perpendicular to the direction in which the terminals are aligned. According to this structure, inclination in a direction perpendicular to the direction in which the terminal modules are aligned can be suppressed by the connection wall along the direction in Which the multiple terminals are aligned.
The retaining member is provided with an inner wall along an outer circumference of at least one of the first and second circuit boards, and the fitting portion is formed so as to be continuous to the inner wall.

By so doing, the fitting portion can be formed by using the structure of the inner wall of the retaining member.
A frame-shaped fitting frame is provided, which forms the fitting portion at the inner wall.
When the terminal module is inserted into the fitting portion, the fitting portion has a restriction portion that contacts the terminal module if an angle of a rotation direction in which the insertion direction is used as an axis is not a normal angle, and restricts the insertion of the terminal module.

Thus, insertion errors of the terminal module can be suppressed.
In the fitting portion, a guide portion is formed, which contacts the terminal module and guides insertion of the terminal module.

Thus, the terminal module can easily be inserted into the fitting portion.
The connecting member is provided with a leg portion that contacts a surface of the first circuit board.

By so doing, when the terminal module is mounted, it can he fitted into the fitting portion to a position at which the leg portion contacts the first circuit board. Thus, an insertion depth of the terminal module can be easily positioned.
The retaining member is provided with a case that houses the first and second circuit boards and the terminal module.

By so doing, the fitting portion can be formed by using the structure of the case.

### Effects of the Invention

According to this invention, the operation of assembling the plurality of terminals to the circuit boards can be simplified.

### BRIEF DESCRIPTION OF THE DRAWINGS

FIG. 1 is a perspective view showing an electrical junction box of an embodiment.

FIG. 2 is a perspective view showing the electrical junction box in a state in which a shielding cover is removed.

FIG. 3 is a perspective view showing a second circuit board to which a control housing is installed.

FIG. 4 is a perspective view showing a state in which a first circuit board and a terminal module are mounted to a retaining member.

FIG. 5 is a plan view showing a state in which the terminal module is fit to a fitting portion of the retaining member.

FIG. 6 is a cross-sectional view along line A-A of FIG. 4.

FIG. 7 is a cross-sectional view along line B-B of FIG. 4.

FIG. 8 is a plan view showing the retaining member.

FIG. 9 is a plan view showing the terminal module.

FIG. 10 is a front view showing the terminal module.

FIG. 11 is a right side view showing the terminal module.

FIG. 12 is a bottom view showing the terminal module.

FIG. 13 is a perspective view showing a state in which the terminal module is fit into the fitting portion of the retaining member.

### MODE TO IMPLEMENT THE INVENTION

### Embodiment

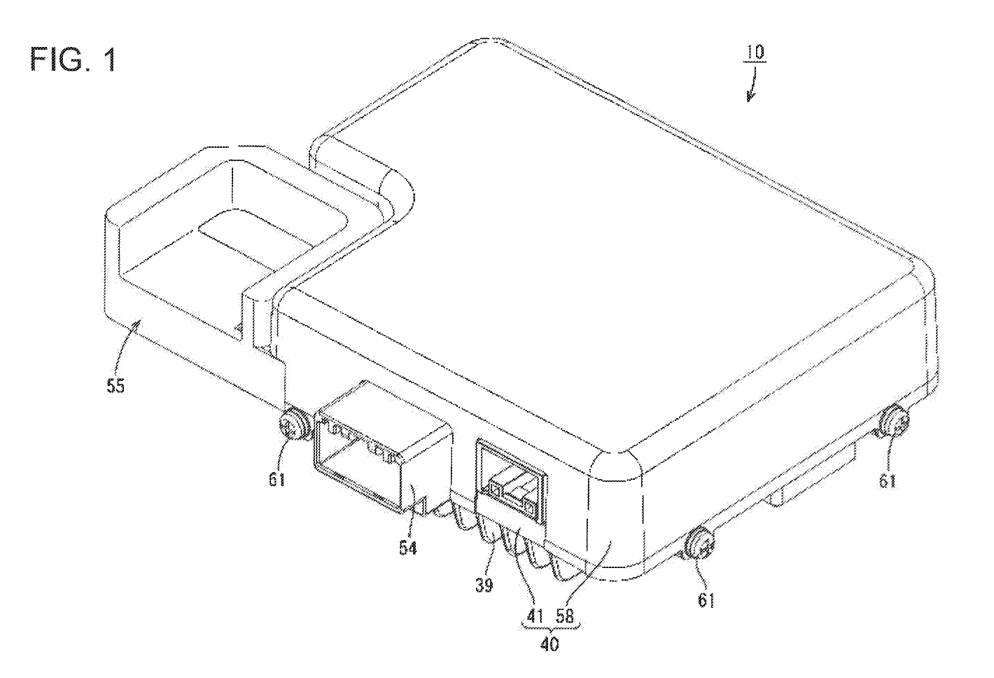

An embodiment is explained with reference to FIGS. 1-3.

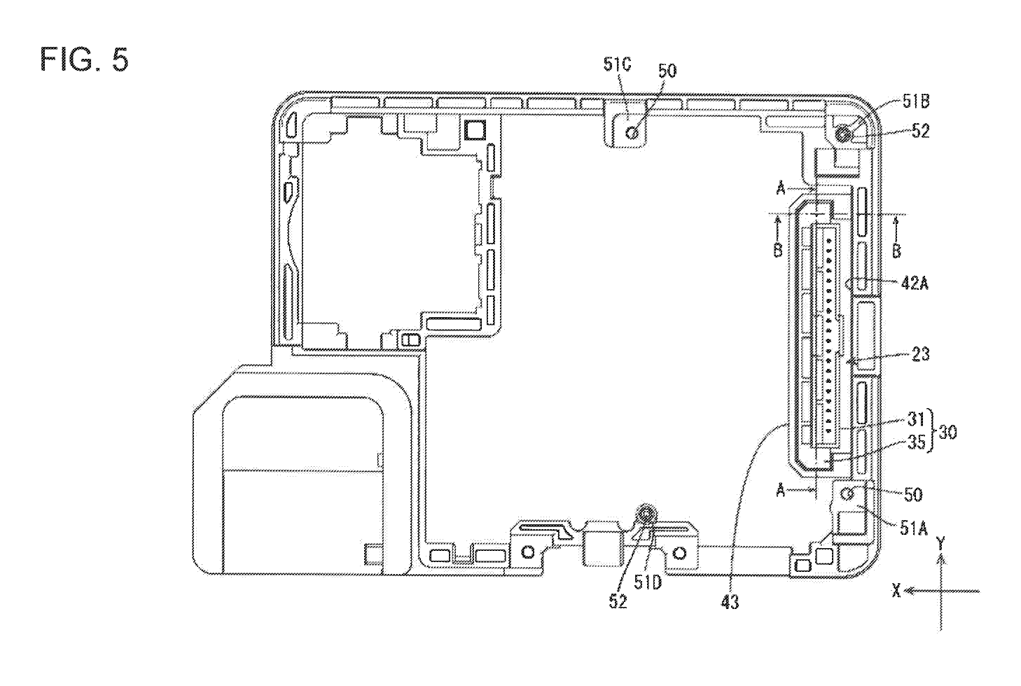

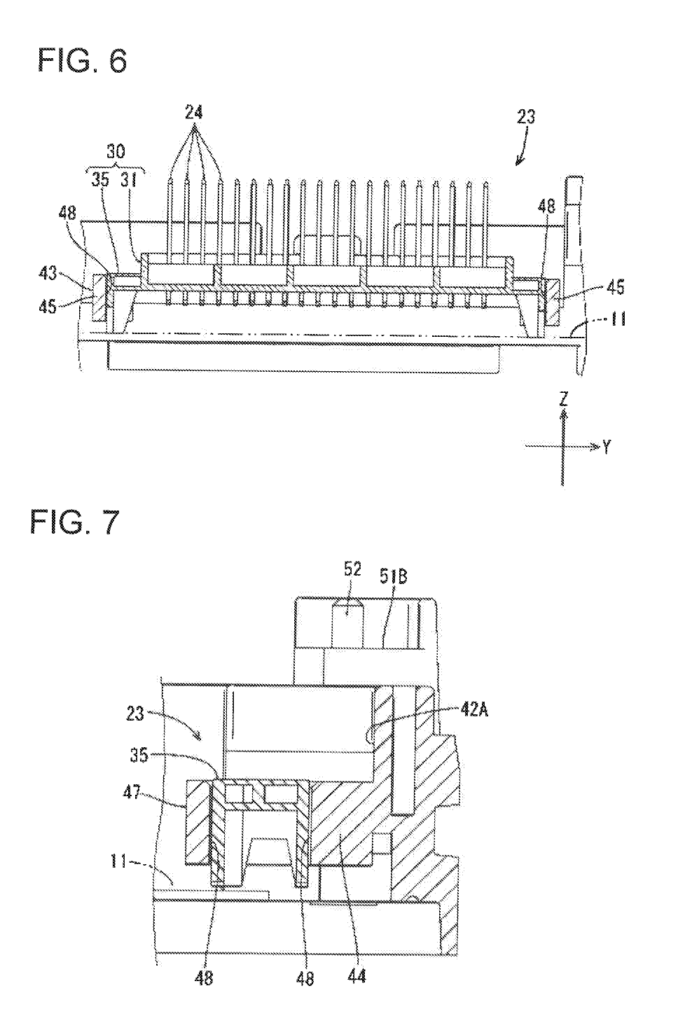

An electrical junction box 10 is arranged, for example, on a power supply path between (i) a power source such as a battery or the like of a vehicle such as an electric vehicle, a hybrid vehicle, or the like and (ii) a load constituted by an onboard electronic component such as a lamp or the like, a drive motor, or the like and can be used for, for example, a DC-DC converter, an inverter, or the like. Hereafter, for purposes of explanation, the directions of FIG. 6 are used as references for an upward/downward direction (Z axis) and a rightward/leftward direction (Y axis). For a forward/backward direction (X axis), the leftward direction of FIG. 5 is used as a forward direction, and the rightward direction of FIG. 5 is used as a backward direction.

### Electrical Junction Box 10

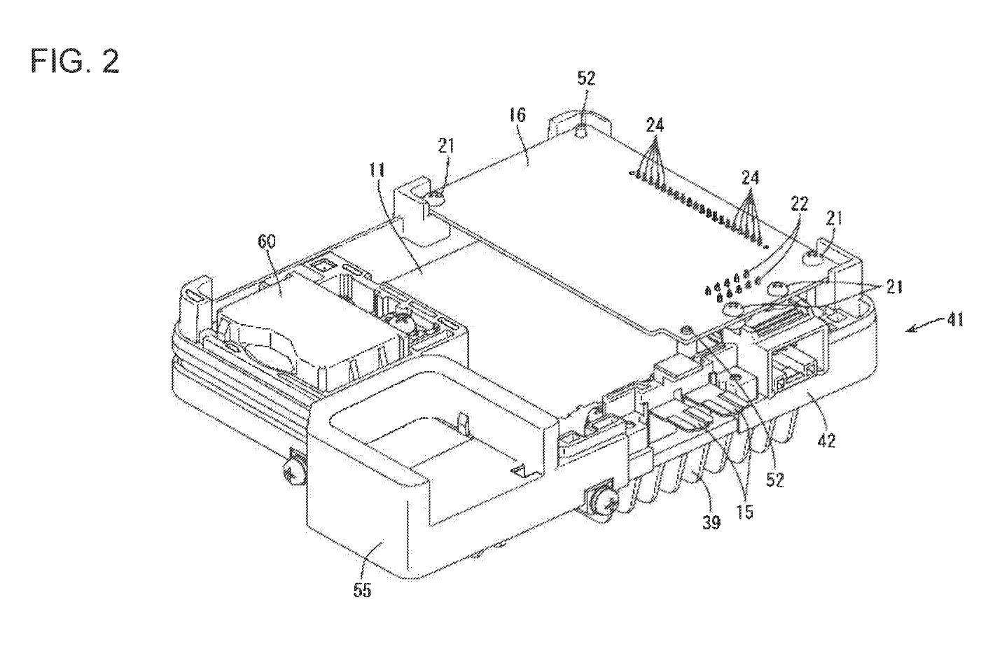

As shown in FIGS. 1 and 2, the electrical junction box 10 is provided with (i) a first circuit board 11, (ii) a second circuit board 16 that is arranged facing the first circuit board 11, (iii) a case 40 that houses the first and second circuit boards 11 and 16, and (iv) a heat-dissipating member 39 that is arranged under the first circuit board 11 and dissipates heat to the outside.

### First Circuit Board 11, Second Circuit Board 16

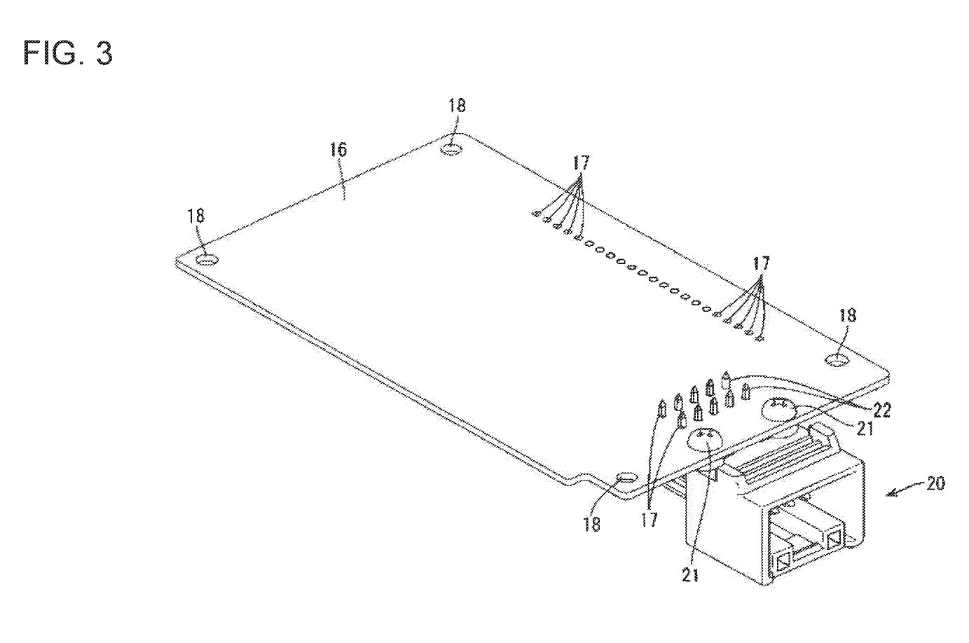

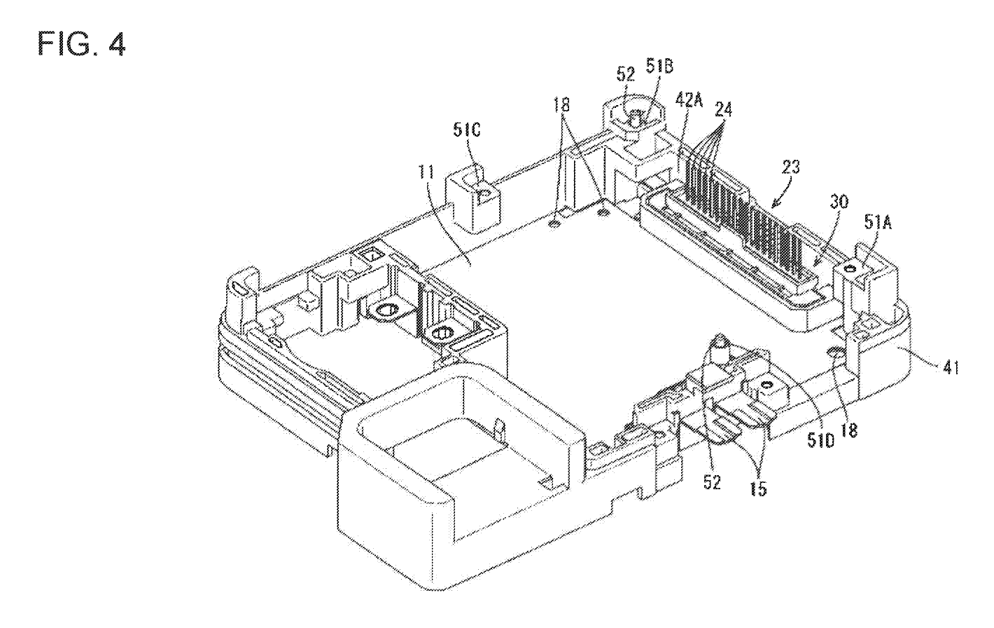

The first and second circuit boards 11 and 16 are provided with (undepicted) electroconductive paths, and undepicted electronic components are mounted to the first and second circuit boards 11 and 16. The electronic components are constituted by a switching element such as an FET (Field Effect Transistor), a capacitor, or the like. As shown in FIGS. 3 and 4, through holes 17 that are aligned on the electroconductive paths and through holes 18 for positioning are formed in the first and second circuit boards 11 and 16. Terminals 24 are inserted through the through holes 17 and soldered.

As shown in FIG. 4, the first circuit board 11 has a rectangular shape that is fit into the inside of a retaining member 41, which is described later, of the case 40. The first circuit board 11 is constituted by a printed circuit board and a bus bar that are stacked to each other. With respect to the printed circuit board, electroconductive paths constituted by copper foil or the like are formed on an insulating plate formed by an insulating material, using a printed circuit technology. Bus bars are formed by punching a metal plate formed of a copper alloy or the like according to the shapes of the electroconductive paths. Insulative adhesive is used to bond the first circuit board 11 and the heat-dissipating member 39. The first circuit board 11 is screw-fastened to the heat-dissipating member 39 via the through holes 18. A plurality of component insertion holes (undepicted) for connecting electronic components to the bus bars is formed in the printed circuit board. End portions of the bus bars are bent in a crank shape, forming connector terminals 15.

As shown in FIGS. 2 and 3, an area of the second circuit board 16 is smaller than that of the first circuit board 11. The second circuit board 16 is fixed to an upper portion of the retaining member 41 in parallel to the first circuit board 11, at a specified spacing from the first circuit board, and has a rectangular shape. With respect to the second circuit board 16, electroconductive paths constituted by copper foil or the like are formed on an insulating plate formed by an insulating material, using a printed circuit technology. A control housing 20 is fixed and screw-fastened to the second circuit board 16, using screws 21. The control housing 20 is formed of synthetic resin and is opened in a rectangular tube shape that can engage with another connector housing. L-shaped control terminals 22 are fixed to the control housing 20.

The electroconductive paths of the first circuit board 11 and the electroconductive paths of the second circuit board 16 are connected by the plurality of terminals 24 of a terminal module 23.

### Terminal Module 23

As shown in FIGS. 10 and 12, the terminal module 23 is provided with (i) the plurality of terminals 24 that are aligned in a row and (ii) a connecting member 30 that connects the plurality of terminals 24, Each terminal 24 is formed of copper, a copper alloy, or the like rind has the same shape. Specifically, each terminal 24 is provided with (i) a first extending portion 25 linearly extending in an upward/downward direction, (ii) a second extending portion 26 arranged rearward from and above the first extending portion 25 and linearly extending in an upward/downward direction, and (iii) a bent portion 27 that extends in an inclined direction so as to connect the first and second extending portions 25 and 26. The terminals 24 can be fixed by press-fitting the second extending portions 26 into respective ones of terminal fixing holes 32 of the connecting member 30. Furthermore, this is not limited to press-fitting. For other embodiments, a terminal module can be formed by insert-molding the plurality of terminals 24.

The connecting member 30 is formed of insulating synthetic resin and is provided with (i) a terminal retaining portion 31 that retains the plurality of terminals 24 and (ii) a pedestal portion 35 that is continuous with a substantially lower half portion of the terminal retaining portion 31 and is placed on the first circuit board 11. The terminal retaining portion 31 has a thick plate shape that extends in a direction along a direction in which the multiple terminals 24 are aligned. The plurality of terminal fixing holes 32 are aligned, which pass through the terminal holding portion 31. At a peripheral portion at an upper surface of the terminal retaining portion 31, a pair of plate-shaped front/back gripping portions 33 protrudes upward, which can be gripped by an operator. By gripping the gripping portions 33, the operator can insert the terminal module 23 into a fitting portion 48, which is described later, of the retaining member 41.

The pedestal portion 35 is provided with (i) an overhanging portion 36 that overhangs beyond the terminal retaining portion 31 in forward and rightward/leftward directions and (ii) leg portions 37 that protrude to the first circuit board 11 side from right and left end portions of the overhanging portion 36. Right and left leg portions 37 are provided in front/rear pairs such that their tip ends become tapered. At an outer surface at positions of the leg portions 37 on the front side (position of corners of the pedestal portion 35), notch portions 38 are formed, which are cut out in an inclined shape.

Additionally, a plurality of concave portions that are cut out in a groove shape is formed in the top surface and the bottom surface of the connecting member 30.

### Heat-Dissipating Member 39

The heat-dissipating member 39 is formed of a metal material with high heat conductivity such as an aluminum alloy, a copper alloy, or the like, The upper surface side is flat, and many heat-dissipating fins are aligned and arranged on the lower surface side.

### Case 40

As shown in FIGS. 1 and 2, the case 40 is provided with (i) the retaining member 41 that is arranged at the upper surface of the heat-dissipating member 39 and is formed of synthetic resin and (ii) a shielding cover 58 that is ted onto the retaining member 41 and is formed of metal.

### Retaining Member 41

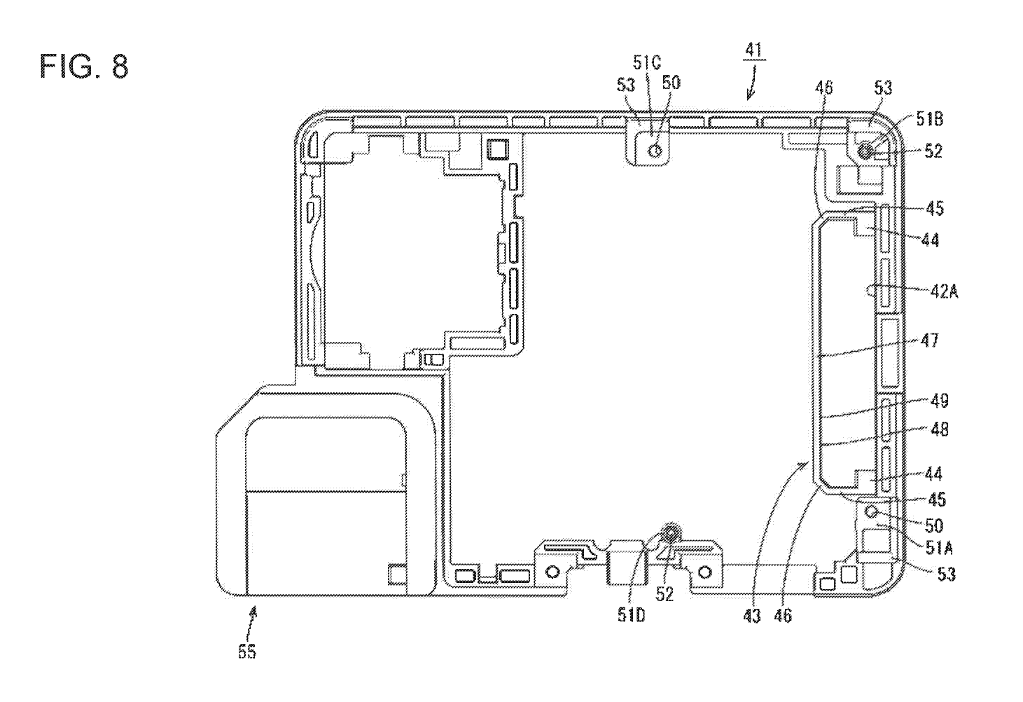

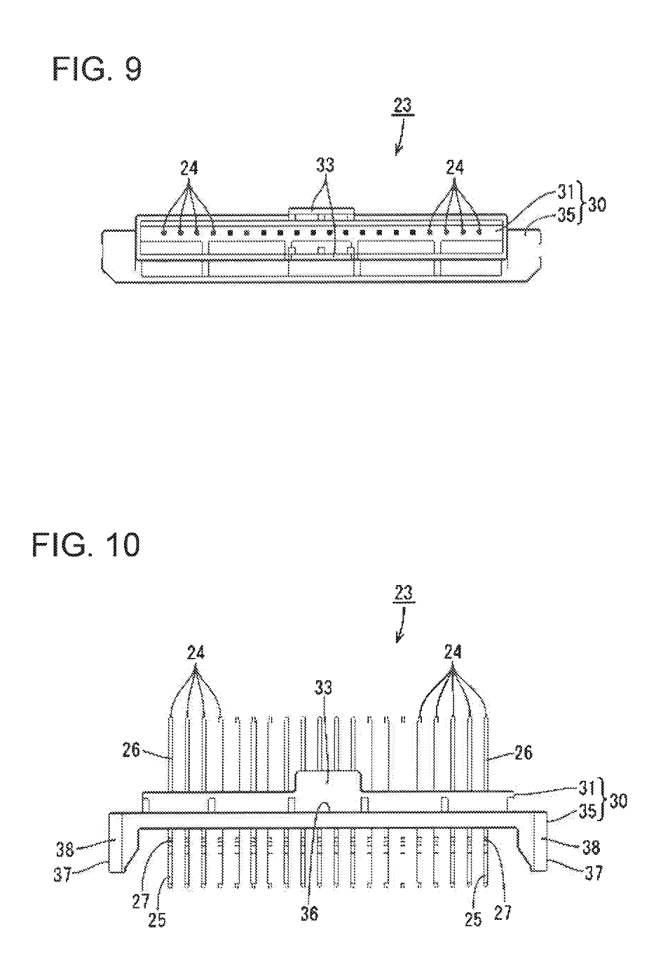

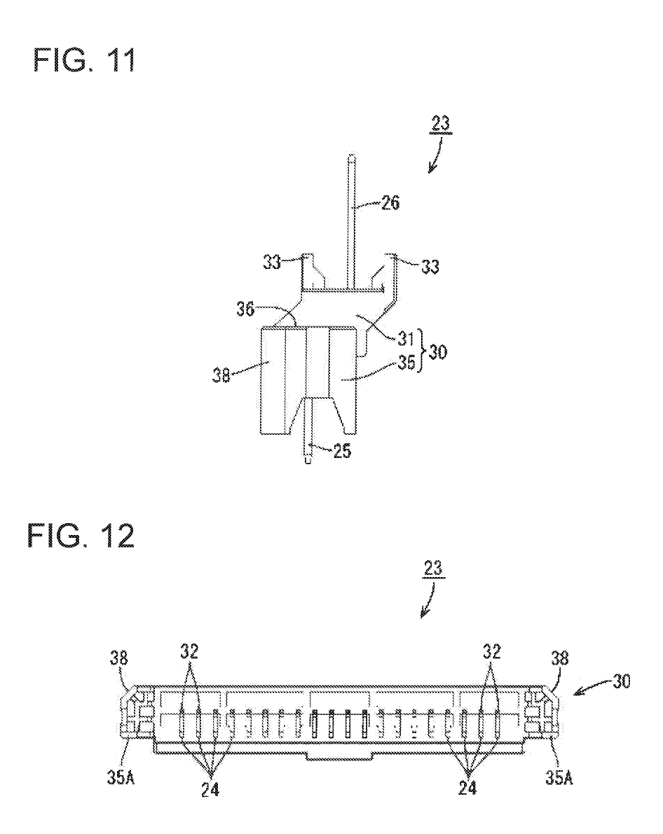

The retaining member 41 is arranged along a peripheral portion of the heat-radiating member 39. A frame-shaped main body 42 that can house the first circuit board 11 therein is provided. A mounting portion 55 is provided, which is arranged outside of the shielding cover 58 and can connect a terminal portion of an electric wire connected to an undepicted external power source. In the main body 42, a portion in which a choke coil 60 is housed is partitioned. As shown in FIG. 8, in an inner wall 42A of the rear end portion of the main body 42, a fitting frame 43 expands inward. The connecting member 30 of the terminal module 23 fits into the fitting frame 43.

The fitting frame 43 is provided with (i) a pair of thick portions 44 that are continuous with the inner wall 42A of the main body 42, (ii) a right/left pair of side walls 45 that are continuous with the respective thick portions 44, (iii) right and left inclined walls 46 (an example of “restriction portions”) that are continuous with the respective side walls 45 and extend in a direction inclined with respect to the side walls 45, and (iv) a connecting wall 47 that connects the right and left side walls 45 via the inclined walls 46. The side walls 45, the inclined walls 46, and the connecting wall 47 are formed at a constant thickness. The inner surface of the fitting frame 43 is defined as a fitting portion 48 into which the pedestal portion 35 of the connecting member 30 is fit. The inside of the upper end portion of the fitting frame 43 is defined as a guide portion 49 that is cut out in a tapering shape. When the terminal module 23 is mounted, the guide portion 49 contacts the connecting member 30 and guides insertion of the terminal module 23.

The height of the fitting frame 43 is set to be a height to a degree at which inclination of the terminal module 23 can be suppressed when the pedestal portion 35 is fit in at a normal position at which it contacts the first circuit board 11.

The fitting portion 48 is made to have a shape and size such that when the pedestal portion 35 is fit in, there is a slight gap between the fitting portion 48 and the pedestal portion 35. Because of this, the pedestal portion 35 is sandwiched (i) between the pair of thick portions 44 and the connecting wall 47 in the forward/backward direction and (ii) the pair of side walls 45 in the rightward/leftward direction (see FIGS. 6 and 7). In a state in which the terminal module 23 is inserted at a normal position at which the lower ends of the leg portions 37 of the pedestal portion 35 contact the first circuit board 11, the top surface of the pedestal portion 35 becomes substantially flush with the top surface of the fitting frame 43.

Here, if the front and back surfaces of the terminal module 23 are inserted to the fitting portion 48 in the opposite direction (180-degree opposite direction), corner portions 35A (see FIG. 12) that are formed at right angles of the pedestal portion 35 contact the inclined walls 46, and insertion of the connecting member 30 into the fitting portion 48 is restricted.

As shown in FIG. 8, on the top portion of the retaining member 41, mounting portions 51A-51D are formed at four locations at which the four corners of the second circuit board 16 are mounted. For a pair of mounting portions 51B, 51D corresponding to a diagonal pair of corners of the second circuit board 16, protruding portions 52, which pass through the through holes 18 of the second circuit board 16, protrude upward from the mounting portions 51B, 51D. The mounting portions 51A, 51C are provided with screw holes 50 that enable screw fastening via the through holes 18 of the second circuit board 16. L-shaped positioning walls 53 into which the corner portions of the second circuit board 16 fit are arranged at the mounting portions 51B-51D.

As shown in FIG. 1, a connector housing 54 is mounted in the vicinity of the mounting portion 51A. The mounting portion 55 houses an undepicted power source side terminal and separates the power source side terminal from the outside. A terminal of an electric power terminal portion connected to an external power source is fixed to the power source side terminal. Electric power from the external power source is supplied to the first circuit board 11 via the power source side terminal.

The shielding cover 58 is formed by performing punching and bending processing to plate-shaped metal formed of aluminum or the like. The lower end portion is fixed to the heat-dissipating member 39 by screwing it to the heat-dissipating member 39 with screws 61, and the shielding cover 58 is connected to a ground via the heat-dissipating member 39.

Assembly of the electrical junction box 10 will be explained.

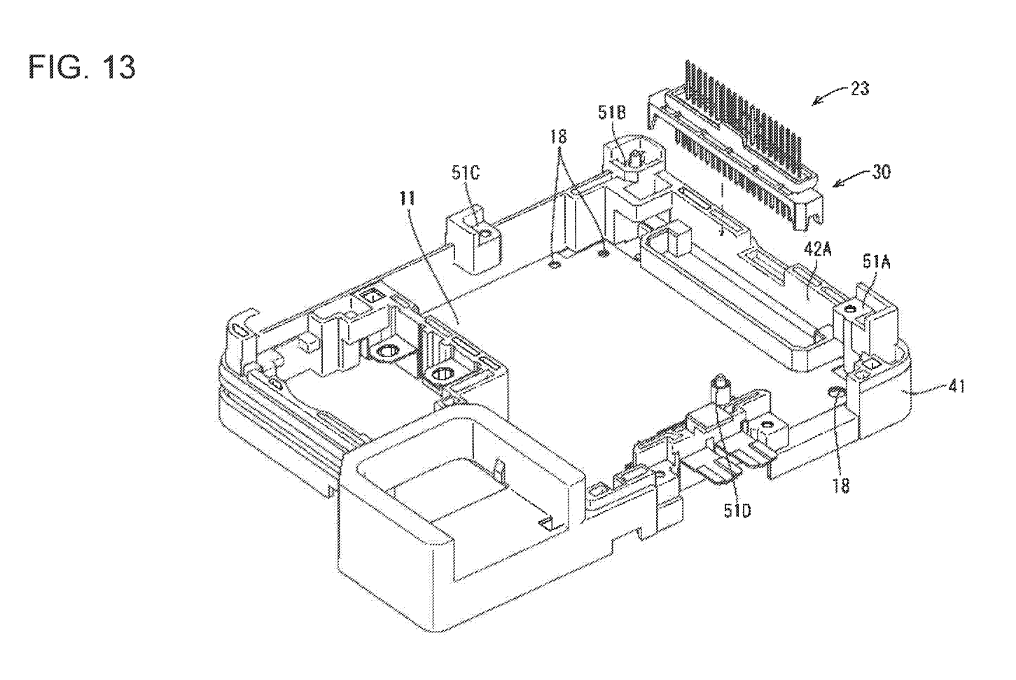

When the first circuit board 11 is stacked on the rear surface of the retaining member 41, the rear end portion of the first circuit board 11 is arranged under the fitting frame 43. Additionally, when the connecting member 30 of the terminal module 23 is fit into the fitting portion 48 at a normal position (FIG. 13), the lower ends of the multiple terminals 24 are passed through the through holes 17 of the first circuit board 11 (FIG. 4). Furthermore, flow-soldering is performed with respect to the first circuit board 11. By so doing, each of the terminals 24 is soldered to an electroconductive path of the first circuit board 11.

Next, the heat-dissipating member 39 is stacked on the rear side of the first circuit board 11, and the first circuit board 11 is screw-fastened to the heat-dissipating member 39.

Additionally, when the second circuit board 16 is placed at a specified position such that the respective corner portions of the second circuit board 16 are positioned at the mounting portions 51A-51D, the upper end portion of each terminal 24 is passed through the respective through hole 17 of the second circuit board 16. Additionally, the second circuit board 16 is screw-fastened to the mounting portions 51A, 51C with the screws 21 such that the second circuit board 16 is fixed, and flow-soldering is performed with respect to the second circuit board 16 (FIG. 2). By so doing, each terminal 24 is soldered to an electroconductive path of the second circuit board 16.

Additionally, by covering the assembly with the shielding cover 50 and screw-fastening it to the heat-dissipating member 39 with the screws 61, the electrical junction box 10 is formed (FIG. 1).

Operations and effects of this embodiment be explained.

According to this embodiment, if the connecting member 30 of the terminal module 23 is fit into the fitting portion 48 of the retaining member 41, the position of the plurality of terminals 24 with respect to the retaining member 41 can be fixed via the connecting member 30. Thus, even if a jig is not used, the plurality of terminals 24 can be connected to the electroconductive paths of the first and second circuit boards 11 and 16. Thus, an operation of assembling the plurality of terminals 24 to the circuit boards can be simplified.

Additionally, if the terminal module 23 has a long shape in a direction in which the terminals 24 are aligned, inclination of the terminal module 23 is easily generated in a direction perpendicular to the direction in which the terminals 24 are aligned. However, the inclination of the terminal module 23 can be suppressed by having the connecting wall 47 that is arranged along the direction in which the plurality of terminals 24 are aligned and connects the pair of side walls 45. By so doing, for the direction in which the plurality of terminals 24 are aligned, the position and posture of the terminal module 23 can be retained by the pair of side walls 45, and for the direction perpendicular to the direction which the plurality of terminals 24 are aligned, the position and posture of the terminal module 23 can be retained by the connecting wall 47 and the thick portions 44.

Furthermore, the retaining member 41 is provided with the inner wall 42A that extends along the outer periphery of at least one of the first circuit board 11 and the second circuit board 16. The fitting portion 48 is formed so as to be continuous with the inner 42A.

Thus, the fitting portion 48 can be formed by using the structure of the inner wall 41A of the retaining member 41.

Additionally, when the terminal module 23 is inserted into the fitting portion 48, the fitting portion 48 is provided with the inclined walls 46 (restriction portions) that contact the terminal module 23 if the front and back surfaces of the terminal module 23 are reversed (if the angle in a rotation direction in which the insertion direction is used as an axis is not the normal angle) and restricts the insertion of the terminal module.

Thus, insertion errors of the terminal module 23 can be suppressed.

Furthermore, in the fitting portion 48, the guide portion 49 is formed, which contacts the terminal module 23 and guides insertion of the terminal module 23.

Thus, the terminal module 23 can be easily inserted into the fitting portion 48.

Additionally, the connecting member 30 is provided with the leg portions 37 that contact a surface of the first circuit board 11.

By so doing, when the terminal module 23 is mounted, it can be inserted into the fitting portion 48 to a position at which the leg portions 37 contact the first circuit board 11. Thus, an insertion depth of the terminal module 23 can easily be positioned.

Additionally, the retaining member 41 is provided with the case 40 that houses the first and second circuit boards 11 and 16 and the terminal module 23.

By so doing, the fitting portion 48 can be formed by using the structure of the case 40.

### Other Embodiments

This invention is not limited to the above embodiment that was explained with reference to the description and the drawings. For example, the following embodiments are also included in the technical scope of this invention.

(1) The shape and position of the fitting portion 48 are not limited to the structure of the above embodiment. For example, if the shape of the connecting member 30 changes depending on the number of the terminals 24, a shape of the fitting portion corresponding to the shape of the connecting member can be used. Additionally, the fitting portion is not limited to being at the rear wall of the retaining member 41, and other positions can be used. The fitting portion can be arranged at an arbitrary position according to the position of the terminals 24.

(2) The retaining member 41 can retain only one of the first and second circuit boards 11 and 16 or can retain both of them.

(3) The retaining member 41 is provided in the case 40, but a retaining member can also be arranged that is provided with a fitting portion separate from the case.

(4) In the above embodiment, a gap is generated between the connecting member 30 and the fitting portion 48, but the structure is not limited to the above embodiment. A structure is also acceptable such that a gap is not generated between a connecting member and a fitting portion. Furthermore, for example, it is also acceptable that inclination of the terminal module 23 is suppressed in a direction perpendicular to a direction in which the plurality of terminals 24 are aligned, by sandwiching the connecting member 30 between the connecting wall 47 of the fitting portion 48 and the pair of thick portions 44.

### EXPLANATION OF THE SYMBOLS

10: Electrical junction box
11: First circuit board
16: Second circuit board
23: Terminal module
24: Terminals
30: Connecting member
37: Leg portions
40: Case
41: Retaining member
43: Fitting frame
45: Side walls
46: Inclined walls (restriction portions
47: Connecting wall
48: Fitting portion
49: Guide portion

What is claimed is:

1-8. (canceled)

9. An electrical junction box, comprising:
a first circuit board that includes electroconductive paths;
a second circuit board that includes electroconductive paths;
a terminal module including (i) a plurality of terminals that connect the electroconductive paths of the first circuit board and the electroconductive paths of the second circuit board and (ii) an insulative connecting member that connects the plurality of terminals; and
a retaining member that retains at least one of the first and second circuit boards, wherein:
the retaining member has a fitting portion into which the connecting member is fitted.

10. The electrical junction box as set forth in claim 9, wherein:
the fitting portion includes (i) a pair of side walls that are arranged so as to sandwich the connecting member and (ii) a connecting wall that is arranged along a direction in which the plurality of terminals are aligned and connects the pair of side walls.

11. The electrical junction box as set forth in claim 9, wherein:
the retaining member includes an inner wall along an outer periphery of at least one of the first and second circuit boards, and the fitting portion is formed so as to be continuous with the inner wall.

12. The electrical junction box as set forth in claim 11, further comprising:
a fitting frame that forms the fitting portion at the inner wall.

13. The electrical junction box as set forth in claim 9, wherein:
the fitting portion includes a restriction portion that contacts the terminal module when an angle of the fitting portion, in a rotation direction about an axis parallel to a direction in which the terminal module is inserted into the fitting portion, relative to the terminal module is not a normal angle, thereby restricting insertion of the terminal module.

14. The electrical junction box as set forth in claim 9, wherein:
at the fitting portion, a guide portion is formed, which contacts the terminal module and guides insertion of the terminal module.

15. The electrical junction box as set forth in claim 9, wherein:
the connecting member includes a leg portion that contacts a surface of the first circuit board.

16. The electrical junction box as set forth in claim 9, wherein:
the retaining member is provided in a case that houses the first and second circuit boards and the terminal module.
